(19) United States
(12) Patent Application Publication
(10) Pub. No.: US 2016/0135314 A1
(43) Pub. Date: May 12, 2016

(54) Screen Protection Film with Curve Frame

(71) Applicant: Shanghai BENPU Technology Development Co.,Ltd, Shanghai (CN)

(72) Inventors: Fei Ma, Shanghai (CN); Zaiheng Li, Shanghai (CN); Hanbing Liu, Shanghai (CN); Xiaohai Zhao, Shanghai (CN)

(73) Assignee: Shanghai BENPU Technology Development Co.,Ltd

(21) Appl. No.: 14/542,468

(22) Filed: Nov. 14, 2014

(30) Foreign Application Priority Data
Nov. 7, 2014 (CN) 201420664692.5

(51) Int. Cl. H05K 5/03; H04B 1/3888; G06F 3/041

(52) U.S. Cl. CPC H05K 5/03; G06F 3/041; H04B 1/3888

(57) ABSTRACT

A screen protection film with a curve frame includes a lens diaphragm and a frame diaphragm. The lens diaphragm has a first fixed zone; the frame diaphragm has a second fixed zone; the first fixed zone connects with the second fixed zone. The frame diaphragm has the same curve radian as a display screen to be protected. Both the lens diaphragm and the frame diaphragm are made of PET diaphragm material by forming in mold. The screen protection film realizes protection to a whole curve screen. Usually, a curved surface deforms in 3 directions and a stretched frame diaphragm can deform in 3 directions to completely fit in with the radian of the curve screen and cover the whole curve screen; the PET as the base material ensures a good light transmittance. Even in stretching, the light transmittance also reaches more than 85%, surpassing PVC and PP materials.

### CROSS REFERENCE OF RELATED APPLICATION

The present invention claims priority under 35 U.S.C. 119(a-d) to CN 201420664692.5, filed Nov. 7, 2014.

### BACKGROUND OF THE PRESENT INVENTION

1. Field of Invention

The present invention relates to a screen protection film, and more specifically to a screen protection film with a curve frame.

2. Description of Related Arts

In order to realize more advanced design thinking and product differentiation, electronic product and equipment manufacturers have competed to introduce curve smart wristband, watch, mobile phone, tablet computer and curve television, etc. More and more equipment with small, medium or large sized display screens have come into existence and this has become a popular trend in the design circle. Usually a curve display screen has four layers in structure. The first layer is the glass cover plate made through bending formation technology; the second layer is transparent conducting thin film to detect a touch point position; the third layer is non-conducting glass layer to protect the thin film layer and inductor; and a conducting layer to shield internal electric signal. The bent transparent glass cover plate is usually a silicate glass product whose hardness is usually between pencil hardness 3-5H, approaching to the hardness of the metal and the sand and stone in the normal environment and being liable to get scratched resulting in a poor surface appearance. Besides, the unprotected glass cover plate surface contacts such conducting substances as water, oil, stain, etc. These substances, when piling or core-forming, are liable to cause a wrong system judgment on touch point, which is called as touch screen drift in the industry and is a main cause of touch screen failure. Therefore, designing a protective adhesive film fit for the curve glass is able to effectively prevent the screen from being scratched and the touch screen from failing. At present, there are a lot of flat panel display protection products, such as ARM (ARM Station) film, Polyethylene terephthalate (PET) film, Polypropylene (PP) film, Polyvinyl chloride polymer (PVC) film, stain and fingerprint proof liquid coating, etc. However, the curve display protection products are few. The traditional ARM film and PET film are high in hardness and good in stiffness, and are completely unfit for the curve display; the PP film is low in hardness, which is usually used to protect production process; the PVC film is poor in light transmittance, soft and not easy to operate; though the stain and fingerprint proof oil can solve the touch screen drift problem, the thickness thereof after film formation is only between 0.015-0.05 mm, which is unable to enhance the wear resistance property of the display screen.

### SUMMARY OF THE PRESENT INVENTION

In view of the above flaws in the traditional technology, an object of the present invention is to provide a screen protection film with a curve frame. The screen protection film of the present invention not only fits in with a screen completely, but also enhances a surface hardness and reduces a touch screen drift due to surface contamination.

According to the present invention, a screen protection film with a curve frame comprises a lens diaphragm and a frame diaphragm, wherein the lens diaphragm has a first fixed zone; the frame diaphragm has a second fixed zone; the first fixed zone connects with the second fixed zone; and, the frame diaphragm has the same curve radian as a display screen to be protected.

Preferably, a thickness of the frame diaphragm is between 0.2 mm and 0.4 mm, and the frame diaphragm is made of a material whose hardness is between 1 H and 2 H, in such a manner that a tensile depth of the frame diaphragm is greater than or equal to 10 mm.

Preferably, the lens diaphragm and the frame diaphragm are respectively formed in mold by using PET diaphragm material.

Preferably, the lens diaphragm comprises a lens color layer, an anti-glare (AG) treatment layer, a lens PET base material, a lens hardening layer and a functional coating; wherein

the AG treatment layer, the lens PET base material, the lens hardening layer and the functional coating are bonded in order; the lens color layer is provided at one end of the AG treatment layer; and

the first fixed zone is provided on the lens color layer.

Preferably, the lens diaphragm comprises a lens color layer, a glass base material, an explosion-proof film and a functional coating; wherein the glass base material, the explosion-proof film and the functional coating are connected with each other in succession; and

the lens color layer is provided at one end of a lower side of the glass base material, and the first fixed zone is provided on the lens color layer.

Preferably, the functional coating is any one member or more selected from a group consisting of a fingerprint-proof coating, a blue light layer and an anti-peep layer.

Preferably, the frame diaphragm is made by specific cutting in four directions in high tension after being formed in mold using PET diaphragm material.

Preferably, the frame diaphragm comprises a frame base material and a frame color layer; wherein

the second fixed zone, the frame color layer and the frame base material are bonded in order; and

the second fixed zone is a frame adhesive layer.

Preferably, the second fixed zone comprises a fixed zone for the lens diaphragm and a fixed zone for the display screen;

The fixed zone for the lens diaphragm connects with the first fixed zone; the fixed zone for the display screen connects with the display screen to be protected.

Preferably, the frame color layer is made from multiple spray coatings by placing the frame base material in a high tension state.

Comparing with the traditional technology, the present invention has the following beneficial effects.

1. The present invention realizes protection to a whole curve screen. Usually, a curved surface deforms in 3 directions and a stretched frame diaphragm can deform in 3 directions to completely fit in with the radian of the curve screen and cover the whole curve screen.

2. The present invention uses PET as the base material to ensure a good light transmittance. Even in stretching, the light transmittance also reaches more than 85%, surpassing PVC and PP materials.

3. The PET material used by the present invention has a certain surface hardness to resist wearing and scratching. The pretreatment to the PET base material makes the PET to be used have such surface properties as being bacteria resistant, oil resistant, hydrophobic, etc. As a result, the present invention is enhanced in function and extended in application field.

4. A basic function of the frame diaphragm in the present invention is to connect and fix the lens diaphragm with electronic equipment. Moreover, the frame diaphragm protects structural parts of the electronic equipment at the same time to avoid being scratched and bruised.

5. In the present invention, the frame diaphragm is formed in mold. As a result, the thickness of the frame diaphragm is uniform and maintains uniformity after stretching;

6. In the present invention, the frame color layer is made from multiple spray coatings by placing the frame base material in a high tension state. As a result, the frame color maintains uniformity after stretching;

7. In the present invention, the frame diaphragm is made by specific cutting in four directions in high tension after being formed in mold using PET diaphragm material. As a result, the tensile property of the frame diaphragm is improved.

### BRIEF DESCRIPTION OF THE DRAWINGS

These and other features, objects, and advantages of the present invention will become apparent with reference to the following detailed description in the preferred embodiments which are not intended to be limiting and the accompanying drawings.

FIG. 1 is a sketch view of a screen protection film with a curve frame according to preferred embodiments of the present invention.

FIG. 2 is a sketch view of a lens diaphragm according to the preferred embodiments of the present invention.

FIG. 3 is a sketch view of a frame diaphragm according to the preferred embodiments of the present invention.

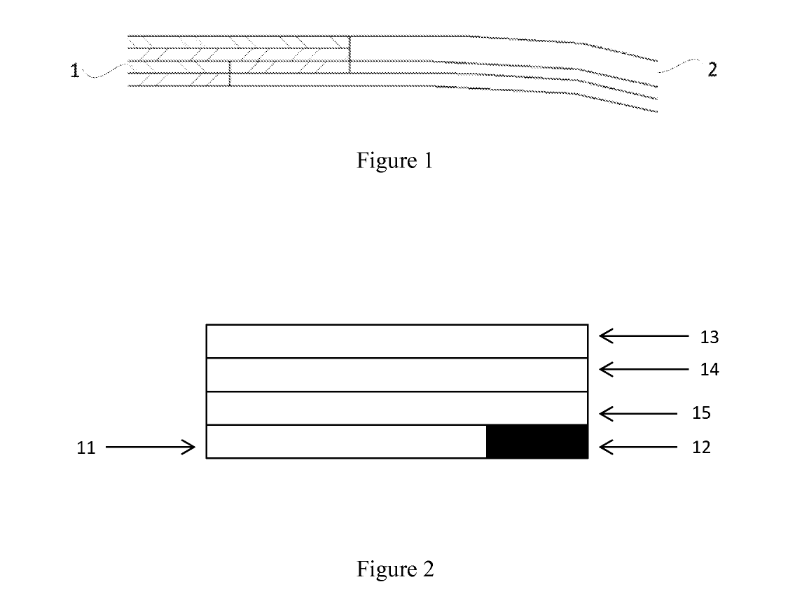

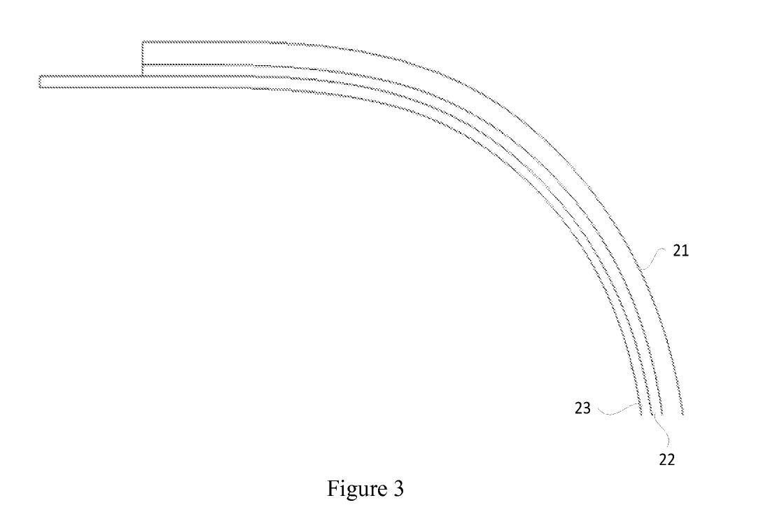

In the figures:
1—lens diaphragm; 2—frame diaphragm; 11—AG treatment layer; 12—lens color layer; 13—functional coating; 14—lens hardening layer; 15—lens PET base material; 21—frame PET base material; 22—frame color layer; and 23—frame adhesive layer.

### DETAILED DESCRIPTION OF THE PREFERRED EMBODIMENT

The present invention is further illustrated combined with the following preferred embodiments. One skilled in the art will understand that the embodiment of the present invention as shown in the drawings and described above is exemplary only and not intended to be limiting. It will thus be seen that the objects of the present invention have been fully and effectively accomplished. Its embodiments have been shown and described for the purposes of illustrating the functional and structural principles of the present invention and is subject to change without departure from such principles. Therefore, this invention includes all modifications encompassed within the spirit and scope of the following claims.

According to preferred embodiments of the present invention, a screen protection film with a curve frame comprises a lens diaphragm 1 and a frame diaphragm 2. The lens diaphragm 1 has a first fixed zone; the frame diaphragm 2 has a second fixed zone; and, the first fixed zone connects with the second fixed zone. The second fixed zone comprises a fixed zone for the lens diaphragm and a fixed zone for a display screen; wherein the fixed zone for the lens diaphragm connects with the first fixed zone; and wherein the fixed zone for the display screen connects with the display screen to be protected.

The frame diaphragm 2 has the same curve radian as the display screen to be protected. Both the lens diaphragm 1 and the frame diaphragm 2 are made from forming in mold using PET diaphragm material. The lens diaphragm 1 also comprises a lens color layer 12, an AG treatment layer 11, a lens PET base material 15, a lens hardening layer 14 and a functional coating 13; the AG treatment layer 11, the lens PET base material 15, the lens hardening layer 14 and the functional coating 13 are bonded in order; the lens color layer 12 is provided at one end of the AG treatment layer 11; and the first fixed zone is provided on the lens color layer 12.

An alternative mode of the frame diaphragm 2 comprises a lens color layer, a glass base material, an explosion-proof film and a functional coating; the glass base material, the explosion-proof film and the functional coating connect with each other in succession; the lens color layer is provided at one end of a lower side of the glass base material, and the first fixed zone is provided on the lens color layer.

The functional coating 13 is any one member or more selected from a group consisting of a fingerprint-proof coating, a blue light layer and an anti-peep layer.

The frame diaphragm 2 is made by specific cutting in four directions in high tension after being formed in mold using PET diaphragm material.

The frame diaphragm 2 comprises a frame base material and a frame color layer 22; the second fixed zone, the frame color layer 22 and the frame base material are bonded in order; the second fixed zone is a frame adhesive layer 23. The frame base material is made of PET diaphragm material, that is, a frame PET base material 21.

A tensile depth of the frame diaphragm 2 is greater than or equal to 10 mm. The frame diaphragm 2 is made of a material whose hardness is from 1 H to 2 H. A thickness of the frame diaphragm 2 is between 0.2 mm and 0.4 mm, and can be stretched after printing of transparent PET sheet to which high tension can be carried out. The surface hardness of 1 H˜2 H meets the normal service requirement of a screen film. The surface hardness which is too high results in a difficulty in stretching, cracking or unevenly stretching; the thickness which is too low is liable to deform the stretching; and the thickness which is too high also results in the difficulty in stretching, cracking or unevenly stretching.

A printed pattern of the frame color layer 22 is arbitrary. Before stretching, different colors and patterns can be printed on a back of the frame diaphragm 2, which is a printing treatment mode executed on the frame color layer 22 which is inside a use layer. That is to say, the frame color layer 22 will not contact with any external object, so that the color is kept from being changed, discolored and worn for a long time. The printing treatment mode, when being applied to a combination with plastic rubber, is namely an IML (In-Mold Decoration) process. The frame color layer 22 is made from multiple spray coatings by placing the frame base material in a high tension state.

The screen protection film with the curve frame provided by the present invention provides a comprehensive protection to a front mobile phone screen and to arc angles on mobile phone plastic part edges; and applies to overall protection to the display screen or a glass cover plate of equipment with an arc screen.

More specifically, the lens diaphragm 1 is made of the transparent PET diaphragm material, but is not limited to using the PET diaphragm material; the lens diaphragm 1 is used to protect the display screen or the glass cover plate. The PET diaphragm material has a certain surface hardness, which can be placed in a lens mold in a high-temperature and high-pressure condition to be stretched by the lens mold according to a pre-designed shape and in the same radian as the display screen of some equipment of a certain model. The PET material per se has a good light transmittance. Even after stretching, the PET material still maintains an excellent light transmitting effect. The lens diaphragm 1 is produced at a high temperature and a high temperature through a lens mold. A stress in the production process is small. After cooling, the lens diaphragm 1 remains stable in dimension in both cold and hot environments with a low shrinkage and a small overall twist. The lens diaphragm 1 is completely consistent in the radian with the display screen whose curved surface is to be matched, and has the dimension 1-3 mm greater than a display area of the display screen. An area of the lens diaphragm 1 whose dimension is equal to the display area of display screen is called a lens working area a1. An area of the lens diaphragm 1 beyond the lens working area a1 is called an adhesive fixing area a2, that is, the first fixed zone.

The frame diaphragm 2 is made of the PET diaphragm material, but is not limited to using PET material. The frame diaphragm 2 is for connecting and fixing the lens diaphragm 1 and electronic equipment, and protecting structural parts of the electronic equipment. Through a pre-made frame mold, the PET diaphragm material is molded at a high temperature and a high pressure, so as to obtain the frame diaphragm 2 having the same surface radian and the same dimension with the electronic equipment to be matched. The PET diaphragm material can be either a diaphragm with a color, or a transparent PET diaphragm remaining to be colored according to practical needs. In an inner side of the frame diaphragm 2, an AB double faced adhesive tape is applied for the whole surface. Then the frame diaphragm 2 applied with the adhesive tape is treated with a die cutting. The area of the frame diaphragm 2 identical to the display area of the display screen in dimension is called an area to be die cut b1, and other area is adhesive fixing area b2, that is, the second fixed zone.

The adhesive fixing area a2 and the adhesive fixing area b2 are adhered through the AB adhesive. The adhesive fixing area b2 is adhered with the electronic equipment through the AB adhesive.

In the lens mold, the lens diaphragm 1 is formed independently. In the frame mold, the PET formed with a color diaphragm or full version printing color is used as the frame diaphragm 2. Then the area to be die cut b1 is removed. Next, the AB adhesive is used to adhere and fix the lens diaphragm 1 formed in the lens mold onto the adhesive fixing area b2 of the frame diaphragm 2. The AB adhesive in adhesive fixing area b2 is also used to fix with the electronic equipment.

### Embodiment 1

The transparent PET diaphragm is formed in the frame mold with the AB adhesive applied on the whole surface. It is found that after the screen protection film is applied on the electronic equipment, it is hard to remove bubbles between the screen protection film and a curve glass of the electronic equipment. As a result, it is not acceptable because of influencing the appearance; moreover, the AB adhesive deforms in 3 directions resulting in an AB adhesive stacking that influences the appearance.

### Embodiment 2

The transparent PET diaphragm is formed in the frame mold and the AB adhesive is merely applied in the adhesive fixing area b2. It is found that the bubble problem is solved, but the AB adhesive stacking problem still exists.

### Embodiment 3

The transparent PET diaphragm is printed in black color or other colors in the adhesive fixing area b2 first, with the area to be die cut remaining transparent, and then delivered into the frame mold for stretching formation. Then the AB adhesive is applied in the adhesive fixing area b2. As the adhesive fixing area b2 has been covered by such colors as black, etc. in printing, no AB adhesive stacking is visible and the poor appearance problem resulting from the AB adhesive stacking is solved. However, another problem appears, that printing ink in the adhesive fixing area b2 appears irregularly after deformation from stretching in multiple directions, with some ink even being stretched to the area to be die cut b1 that blocks the screen.

### Embodiment 4

The lens is formed independently in the lens mold. The diaphragm with color or the PET with full version printing color is used in the frame mold and formed as the frame diaphragm 2. Then the area to be die cut b1 is removed. Then the AB adhesive is used to adhere and fix the lens diaphragm 1 formed in the lens mold onto the adhesive fixing area b2 of the frame diaphragm 2. The double faced adhesive tape in the adhesive fixing area b2 is also used to fix with the electronic equipment. Thus, a part of the lens diaphragm has no AB adhesive and has no bubble left after contacting with the curved screen; the problem that the AB adhesive on the inner side stacks on the curved surface can not be perceived due to being covered by the printing layer. As a result, the AB adhesive stacking is solved.

### Embodiment 5

Based on the embodiment 4, the transparent PET diaphragm is further subject to an antibacterial and oleophobic and hydrophobic surface treatment so that one layer of the functional coating is added to the PET diaphragm. After going through the embodiment 4, friction resistant and oil contamination resistant properties are improved greatly in comparison with using the PET diaphragm simply. Then, a conclusion that the present invention is optimized can be made.

One skilled in the art will understand that the embodiment of the present invention as shown in the drawings and described above is exemplary only and not intended to be limiting. Its embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. A screen protection film with a curve frame comprising: a lens diaphragm and a frame diaphragm; wherein
said lens diaphragm has a first fixed zone; said frame diaphragm has a second fixed zone; said first fixed zone connects with said second fixed zone; and said frame diaphragm has the same curve radian as a display screen to be protected.

2. The screen protection film with the curve frame according to claim 1, wherein said frame diaphragm is 0.2 mm to 0.4 mm thick and said frame diaphragm is made of a material whose hardness is from 1 H to 2 H; and a tensile depth of said frame diaphragm is greater than or equal to 10 mm.

3. The screen protection film with the curve frame according claim 1, wherein both said lens diaphragm and said frame diaphragm are molded by using a polyethylene terephthalate (PET) diaphragm material.

4. The screen protection film with the curve frame according to claim 2, wherein both said lens diaphragm and said frame diaphragm are molded by using a PET diaphragm material.

5. The screen protection film with the curve frame according to claim 3, wherein said lens diaphragm comprises a lens color layer, an anti-glare (AG) treatment layer, a lens PET base material, a lens hardening layer and a functional coating; wherein
said AG treatment layer, said lens PET base material, said lens hardening layer and said functional coating are bonded in order; said lens color layer is provided at one end of said AG treatment layer; and
said first fixed zone is provided on said lens color layer.

6. The screen protection film with the curve frame according to claim 4, wherein said lens diaphragm comprises a lens color layer, an AG treatment layer, a lens PET base material, a lens hardening layer and a functional coating; wherein
said AG treatment layer, said lens PET base material, said lens hardening layer and said functional coating are bonded in order; said lens color layer is provided at one end of said AG treatment layer; and
said first fixed zone is provided on said lens color layer.

7. The screen protection film with the curve frame according to claim 1, wherein said lens diaphragm comprises a lens color layer, a glass base material, an explosion-proof film and a functional coating; wherein said glass base material, said explosion-proof film and said functional coating connect with each other in succession; and
said lens color layer is provided at one end of a lower side of said glass base material, and said first fixed zone is provided on said lens color layer.

8. The screen protection film with the curve frame according to claim 5, wherein said functional coating is any one member or more selected from a group consisting of a fingerprint-proof coating, a blue light proof layer and an anti-peep layer.

9. The screen protection film with the curve frame according to claim 6, wherein said functional coating is any one member or more selected from a group consisting of a fingerprint-proof coating, a blue light proof layer and an anti-peep layer.

10. The screen protection film with the curve frame according to claim 7, wherein said functional coating is any one member or more selected from a group consisting of a fingerprint-proof coating, a blue light proof layer and an anti-peep layer.

11. The screen protection film with the curve frame according to claim 3, wherein said frame diaphragm is made by specific cutting in four directions in high tension after being molded using said PET diaphragm material.

12. The screen protection film with the curve frame according to claim 4, wherein said frame diaphragm is made by specific cutting in four directions in high tension after being molded using said PET diaphragm material.

13. The screen protection film with the curve frame according to claim 1, wherein said frame diaphragm comprises a frame base material and a frame color layer; wherein
said second fixed zone, said frame color layer and said frame base material are bonded in order; and
said second fixed zone is a frame adhesive layer.

14. The screen protection film with the curve frame according to claim 13, wherein said second fixed zone comprises a fixed zone for said lens diaphragm and a fixed zone for the display screen; wherein
said fixed zone for said lens diaphragm connects with said first fixed zone; said fixed zone for the display screen connects with the display screen to be protected.

15. The screen protection film with the curve frame according to claim 14, wherein said frame color layer is made from multiple spray coatings by placing said frame base material in a high tension state.
